(19) United States
(12) Patent Application Publication
(10) Pub. No.: US 2025/0241082 A1
(43) Pub. Date: Jul. 24, 2025

(54) IMAGE SENSOR

(71) Applicant: SAMSUNG ELECTRONICS CO., LTD., Suwon-si (KR)

(72) Inventors: Eunjung LEE, Suwon-si (KR); Takekazu Shinohara, Suwon-si (KR)

(73) Assignee: SAMSUNG ELECTRONICS CO., LTD., Suwon-si (KR)

(21) Appl. No.: 18/792,086

(22) Filed: Aug. 1, 2024

(30) Foreign Application Priority Data
Jan. 23, 2024 (KR) 10-2024-0010356

(51) Int. Cl. H01L 27/146

(52) U.S. Cl. CPC H10F 39/811; H10F 39/8037; H10F 39/805; H10F 39/807

(57) ABSTRACT

An image sensor includes a substrate including a first surface and a second surface opposing the first surface; a first photoelectric conversion region; a floating diffusion region; a transfer gate configured to move charges generated in the first photoelectric conversion region to the floating diffusion region; a first conductive layer electrically connected to the transfer gate and vertically overlapping with the transfer gate; and a first vertical contact including a first surface and a second surface, wherein the first surface of the vertical contact is connected to the first conductive layer, wherein the first vertical contact is vertically overlapping with the first conductive layer, wherein the first surface of the first vertical contact has a first width in a second direction, wherein the first conductive layer has a second width at least 1.5 times greater than the first width.

### CROSS-REFERENCE TO RELATED APPLICATION(S)

This application claims the benefit under 35 USC 119(a) of Korean Patent Application No. 10-2024-0010356 filed on Jan. 23, 2024 in the Korean Intellectual Property Office, the entire disclosure of which is herein incorporated by reference for all purposes.

### BACKGROUND

One or more example embodiments of the disclosure relate to an image sensor.

Image sensors are semiconductor-based sensors that receive light and generate generating electrical signals, and may include a pixel array having a plurality of pixels, a logic circuit that drives the pixel array and generate an image, and the like. Each pixel may include a photodiode and a pixel circuit that converts charges generated by the photodiode into an electrical signal. As a number of pixels included in an image sensor increases and a size of a respective pixel decreases, various methods have been proposed to effectively form elements that are disposed in the respective pixel to provide a pixel circuit.

### SUMMARY

Example embodiments provide an image sensor in which a damage to a device that forms a pixel circuit may be significantly reduced during forming a via contact and performance may be improved by forming an extended pattern for a contact on the device.

According to an aspect of one or more example embodiments, an image sensor includes a substrate including a first surface and a second surface opposing the first surface; a first photoelectric conversion region for a first pixel in the substrate; a floating diffusion region in the substrate; a transfer gate configured to move charges generated in the first photoelectric conversion region to the floating diffusion region; a first conductive layer configured to electrically connect to the transfer gate and vertically overlapping with the transfer gate in a first direction perpendicular to the first surface of the substrate; and a first vertical contact including a first surface and a second surface, wherein the first surface of the vertical contact is configured to connect to the first conductive layer, wherein the first vertical contact is vertically overlapping with the first conductive layer in the first direction, wherein the first surface of the first vertical contact has a first width in a second direction perpendicular to the first direction, wherein the first conductive layer has a second width in the second direction and the second width is at least 1.5 times greater than the first width, wherein the first conductive layer is spaced apart from the first surface of the substrate, and wherein the transfer gate is in contact with the first surface of the substrate.

According to an aspect of one or more example embodiments, an image sensor includes a substrate including a first surface and a second surface opposing the first surface; a first photoelectric conversion region for a first pixel in the substrate; a second photoelectric conversion region for a second pixel in the substrate; a device isolation film between the first pixel and the second pixel; a floating diffusion region in the substrate; a transfer gate configured to move charges generated in the first photoelectric conversion region to the floating diffusion region; a first conductive layer configured to electrically connect to the transfer gate; and a first vertical contact including a first surface, the first surface in contact with the first conductive layer, wherein the transfer gate, the first conductive layer, and the first vertical contact are vertically overlapping with each other in a first direction perpendicular to the first surface of the substrate, wherein the first surface of the first vertical contact has a first width in a second direction perpendicular to the first direction, wherein the first conductive layer has a second width in the second direction and the second width is greater than the first width, wherein the first conductive layer is spaced apart from the first surface of the substrate, wherein the transfer gate is in contact with the first surface of the substrate, and wherein the first conductive layer is offset from the device isolation film in the second direction.

### BRIEF DESCRIPTION OF DRAWINGS

The above and other aspects, features, and advantages of the disclosure will be more clearly understood from the following detailed description, taken in conjunction with the accompanying drawings, in which:

FIG. 1 is a simple block diagram of an image sensor according to one or more example embodiments;

FIG. 2 is a circuit diagram schematically illustrating a pixel circuit according to one or more example embodiments;

FIG. 3 is a diagram schematically illustrating pixels of the image sensor of FIG. 2;

FIGS. 4A and 4B are cross-sectional views illustrating a cross-section of one of the pixels of FIG. 3;

FIGS. 5A and 5B are enlarged views of a portion of FIG. 4A;

FIGS. 6 and 7 are enlarged views of pixels of an image sensor according to one or more example embodiments;

FIG. 8 is a diagram schematically illustrating pixels of an image sensor according to one or more example embodiments;

FIG. 9 is a cross-sectional view illustrating a cross-section of pixels of FIG. 8;

FIG. 10A is a circuit diagram schematically illustrating a pixel circuit of an image sensor according to one or more example embodiments, and FIG. 10B is a diagram schematically illustrating the pixel circuit of FIG. 10A; and

FIGS. 11A to 11H are cross-sectional views illustrating a method of manufacturing pixels of the image sensor of FIG. 4A.

### DETAILED DESCRIPTION

Hereinafter, one or more example embodiments will be described with reference to the accompanying drawings.

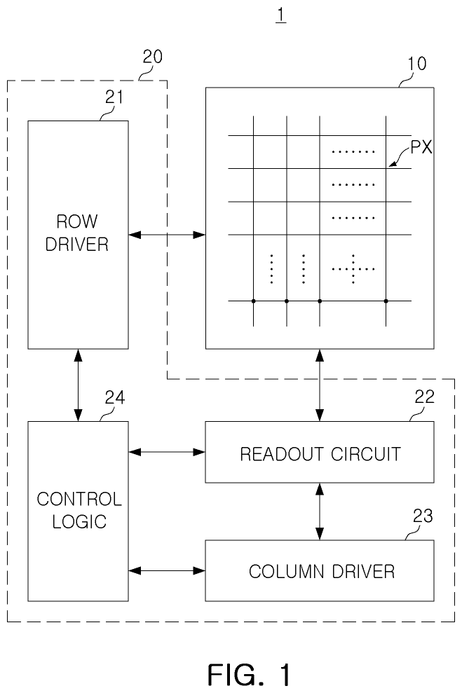

FIG. 1 is a simplified block diagram of an image sensor according to one or more example embodiments.

Referring to FIG. 1, an image sensor 1 may include a pixel array 10, a logic circuit 20 and the like.

The pixel array 10 may include a plurality of pixels PX disposed in an array in a plurality of rows and a plurality of columns. Each of the plurality of pixels PX may include at least one photoelectric conversion element that generates charge in response to light, a pixel circuit that generates a pixel signal corresponding to the charge generated by the photoelectric conversion element, and the like. The photoelectric conversion element may include a photodiode including a semiconductor material, and/or an organic photodiode including an organic material.

For example, the pixel circuit may include a floating diffusion, a transfer transistor, a reset transistor, a driving transistor, a selection transistor, and the like. A configuration of the pixel PX may vary depending on example embodiments. For example, each of the pixels PX may include an organic photodiode containing an organic material, or may be implemented as a digital pixel. When the pixels PX are implemented as digital pixels, each of the pixels PX may include an analog-to-digital converter for outputting a digital pixel signal.

The logic circuit 20 may include circuits for controlling the pixel array 10. For example, the logic circuit 20 may include a row driver 21, a readout circuit 22, a column driver 23, control logic 24, and the like. The row driver 21 may drive the pixel array 10 in units of row lines. For example, the row driver 21 generates a transmission control signal for controlling the transfer transistor of the pixel circuit, a reset control signal for controlling the reset transistor, a selection control signal for controlling the selection transistor, and the like, and may input the generated signals to the pixel array 10 on a basis of a row line.

The readout circuit 22 may include a correlated double sampler (CDS), an analog-to-digital converter (ADC), and the like. Correlated double samplers may be connected to the pixels PX through column lines. The correlated double samplers may read pixel signals through column lines from pixels PX connected to a row line selected by the row line selection signal of the row driver 21. The analog-to-digital converter may convert the pixel signal detected by the correlated double sampler into a digital pixel signal and transmit the converted signal to the column driver 23.

The column driver 23 may include a latch or a buffer circuit capable of temporarily storing a digital pixel signal, an amplifier circuit, and the like, and may process the digital pixel signal received from the readout circuit 22. The row driver 21, the readout circuit 22, and the column driver 23 may be controlled by the control logic 24. The control logic 24 may include a timing controller for controlling an operation timing of the row driver 21, the readout circuit 22, the column driver 23, and the like.

Among the pixels PX, pixels PX disposed at the same position in a horizontal direction may share the same column line. For example, pixels PX disposed at the same position in a vertical direction may be simultaneously selected by the row driver 21 and output a pixel signal through column lines. In example embodiments, the readout circuit 22 may simultaneously obtain pixel signals from the pixels PX selected by the row driver 21 through column lines. The pixel signal may include a reset voltage and a pixel voltage, and the pixel voltage may be a voltage in which the charge generated in response to light in each of the pixels PX is reflected in the reset voltage.

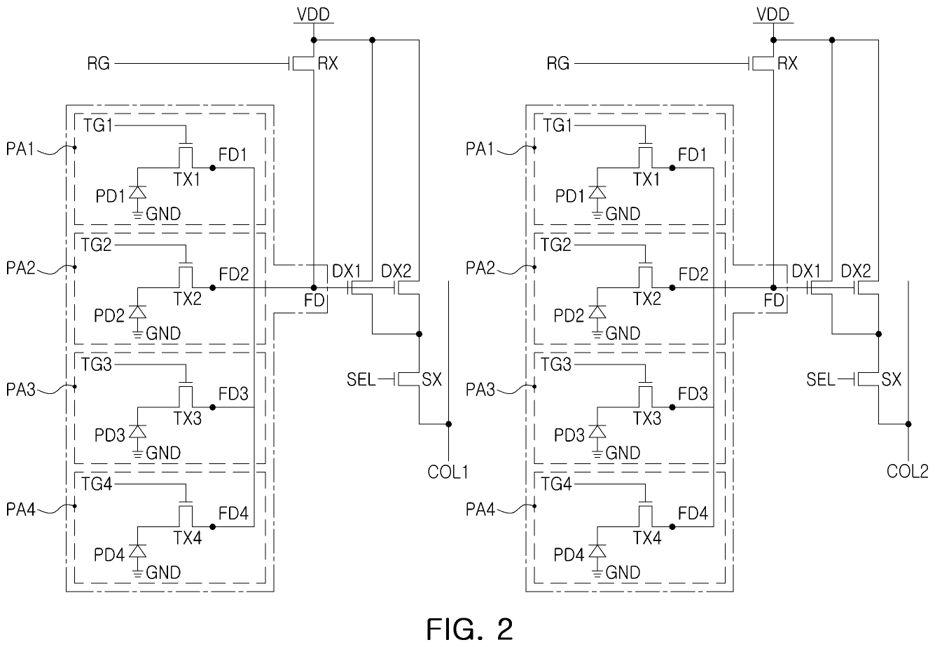

FIG. 2 illustrates an example of a pixel circuit of an image sensor according to one or more example embodiments.

Referring to FIG. 2, each of the plurality of pixels (PX in FIG. 1) may include a photoelectric conversion element PD and a pixel circuit, and the pixel circuit may include a transfer transistor TX, a reset transistor RX, a selection transistor SX, a driving transistor DX, and the like. Additionally, the pixel circuit may further include a floating diffusion region FD in which charges generated in the photoelectric conversion element PD are accumulated.

Hereinafter, the photoelectric conversion element PD will be described as a photodiode, which is an example of the photoelectric conversion element PD.

A photodiode PD may generate and accumulate charges in response to light incident from the outside. The photodiode PD may be replaced with a photo transistor, a photo gate, a pinned photodiode, or the like depending on example embodiments.

The transfer transistor TX may be turned on or off by a transfer control signal input to the transmission gate TG. The transfer transistor TX may move charges generated in the photodiode PD to the floating diffusion region FD. The floating diffusion region FD may store charges generated in the photodiode PD. The voltage output by the driving transistor DX may vary depending on an amount of charge accumulated in the floating diffusion region FD.

The reset transistor RX may reset the voltage of the floating diffusion region FD by removing charges accumulated in the floating diffusion region FD. The drain electrode of the reset transistor RX may be connected to the floating diffusion region FD, and the source electrode may be connected to the power supply voltage VDD. When the reset transistor RX is turned on, the power supply voltage VDD connected to the source electrode of the reset transistor RX is applied to the floating diffusion region FD, and the charge accumulated in the floating diffusion region FD of the reset transistor RX may be removed.

The driving transistor DX may operate as a source follower buffer amplifier. The driving transistor DX may amplify the voltage change in the floating diffusion region FD and output the same to column lines COL1 and COL2.

The selection transistor SX may select pixels PX to be read in row units from among the plurality of pixels PX. When the selection transistor SX is turned on, the voltage of the driving transistor DX may be output to the column lines COL1 and COL2. For example, when the selection transistor SX is turned on, a reset voltage or a pixel voltage may be output through the column lines COL1 and COL2.

Each of the pixels PX may further include a ground area GND that may receive a ground voltage. Accordingly, each of the pixels PX may include a ground area GND, a photodiode PD, a transfer transistor TX, a reset transistor RX, a selection transistor SX, and a driving transistor DX.

On the other hand, as illustrated in FIG. 2, two or more pixels PX adjacent to each other may share at least some of the transistors included in the pixel circuit. For example, four pixels PX adjacent to each other may share a reset transistor RX, driving transistors DX1 and DX2, and a selection transistor SX.

The four adjacent pixels PX may include, within pixel areas PA1-PA4, transfer transistors TX1-TX4 with photodiodes PD1-PD4, a ground area GND and transmission gates TG1-TG4, and floating diffusion regions FD1-FD4, respectively.

In an example, a first pixel area PA1 in which the first pixel of the four pixels PX is placed may include a ground area GND, a first photodiode PD1, a first floating diffusion region FD1, and a first transfer transistor TX1 having a first transmission gate TG1. In the first pixel area PA1, the first photodiode PD1 may be connected to the first floating diffusion region FD1 through the first transfer transistor TX1. Likewise, the second to fourth photodiodes PD2-PD4 of the second to fourth pixel areas PA2-PA4 in which the second to fourth pixels of the four pixels PX are respectively disposed may be connected to the second to fourth floating diffusion regions FD2-FD4 through the second to fourth transfer transistors TX2-TX4, respectively, wherein the second to fourth transfer transistors TX2-TX4 include second to fourth transmission gates TG2-TG4, respectively.

In four adjacent pixels PX, the first to fourth floating diffusion regions FD1-FD4 may be connected to each other by interconnection or the like to operate as one floating diffusion region FD, and the first to fourth transfer transistors TX1-TX4 may be commonly connected to the one floating diffusion region FD in which the first to fourth floating diffusion regions FD1-FD4 are connected to each other.

A pixel circuit shared by four adjacent pixels PX may include a reset transistor RX, first and second driving transistors DX1 and DX2, and a selection transistor SX. The reset transistor RX may be controlled by a reset control signal RG, and the selection transistor SX may be controlled by a selection control signal SEL.

For example, each of the four pixel areas PA1-PA4 may further include one transistor in addition to the transfer transistor TX. Among the four additional transistors included in the four pixel areas PA1-PA4, two additional transistors may be connected in parallel to provide first and second driving transistors DX1 and DX2, and of the two remaining additional transistors, one may be configured to serve as a selection transistor SX, and the other may be configured to provide a reset transistor RX.

The pixel circuit described with reference to FIG. 2 is only an example and the disclosure is not limited to this example. For example, one of the four transistors may be assigned as a driving transistor DX, one may be assigned as a selection transistor SX, another may be assigned as a reset transistor RX, and the remaining one may be allocated as a dual conversion gain transistor DCX connected to the reset transistor RX in series, thereby implementing an image sensor capable of adjusting a conversion gain of the pixel. Alternatively, the pixel circuit may vary depending on a number of transistors included in each of the pixels PX.

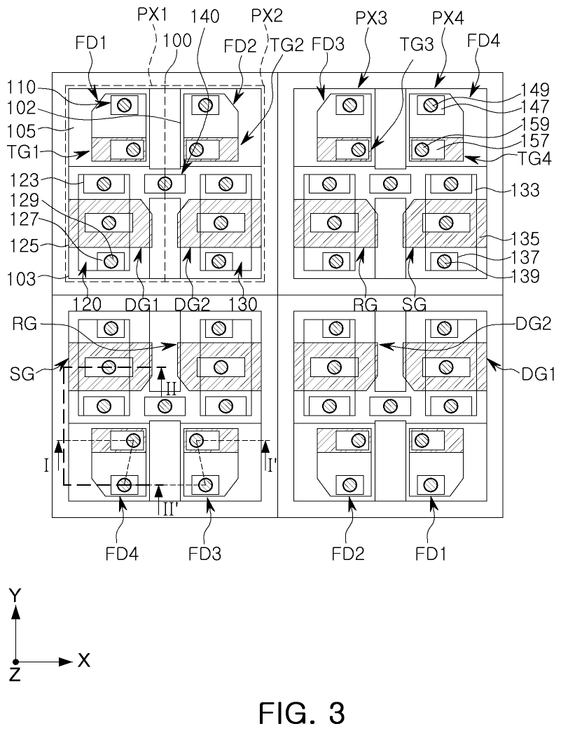

Hereinafter, the pixel of FIG. 2 will be described with reference to FIGS. 3 to 5B.

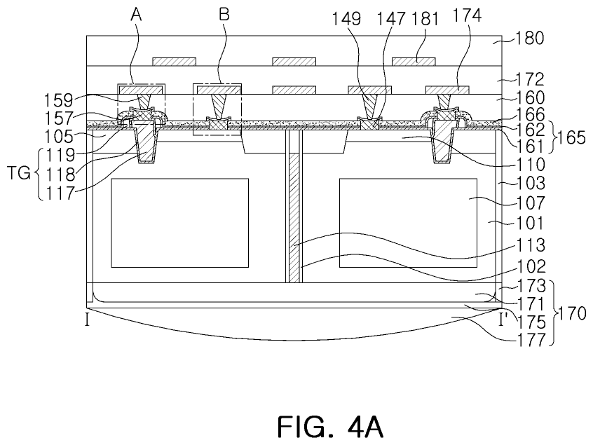

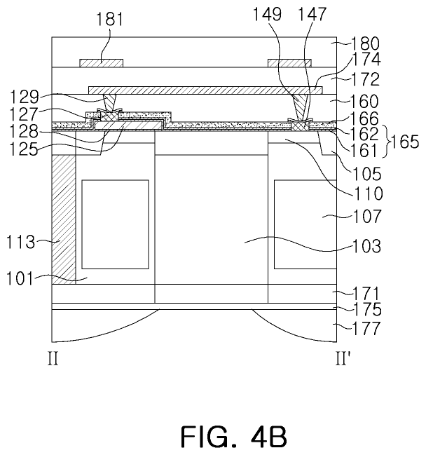

FIG. 3 is a diagram schematically illustrating the pixels of the image sensor 1 of FIG. 2, and FIGS. 4A and 4B are cross-sectional views illustrating a cross section of one of the pixels of FIG. 3.

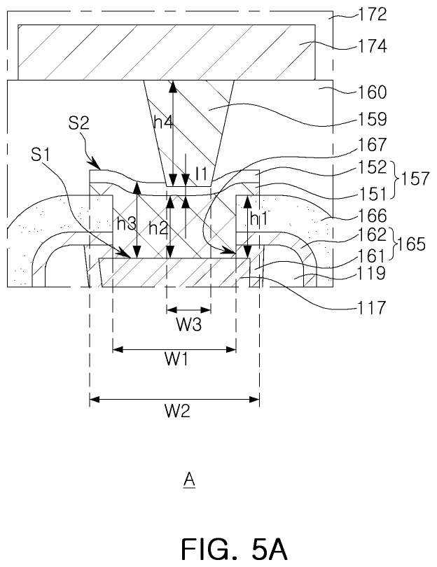

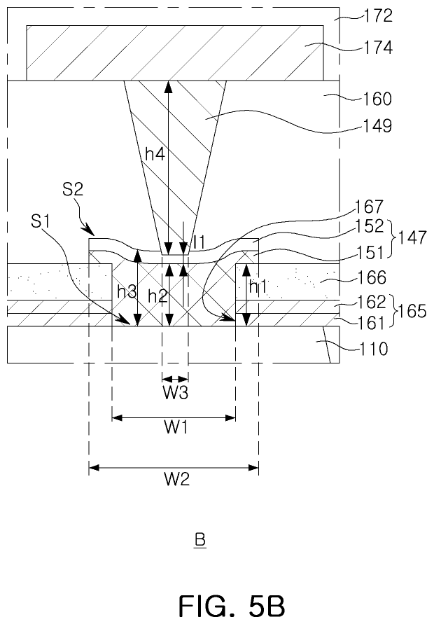

FIG. 4A is a cross-sectional view taken along line I-I′ of FIG. 3, and FIG. 4B is a cross-sectional view taken along line II-II′ of FIG. 3. FIG. 5A is an enlarged illustration of an area ‘A’ of FIG. 4A, and FIG. 5B is an enlarged illustration of an area ‘B’ of FIG. 4A.

Referring to FIG. 3, pixels 100 of the image sensor 1 according to one or more example embodiments may be distinguished from other surrounding pixels by a pixel separator 103. One pixel 100 may include a pixel circuit area disposed inside the pixel separator 103. For example, the pixel circuit area includes two pixel areas PX1 and PX2 or PX3 and PX4, and each pixel area PX1, PX2, PX3, PX4 may include one floating diffusion region 110, one transmission gate structure 115, at least one transistor 120, 130, and the like. Respective pixel areas PX1 and PX2 or PX3 and PX4 within one pixel circuit area may be spaced apart from each other by an intermediate separation area 102, but the disclosure is not limited thereto.

Elements of two pixel areas PX1 and PX2 or PX3 and PX4 disposed in one pixel circuit area may be disposed symmetrically with respect to the intermediate separation area 102. The intermediate separation area 102 may include an intermediate separation area 102 extending upwardly from an intermediate position within one pixel circuit area and an intermediate separation area 102 extending downwardly from an intermediate position within one pixel circuit area, and the two intermediate separation areas 102 may be spaced apart from each other in a central area of the one pixel circuit area. A ground area GND may be placed in the central area.

The floating diffusion region 110 in respective pixel areas PX1, PX2, PX3, and PX4 may be an area doped with a first conductivity-type impurity and may be an area in which charges generated in a photodiode 107 accumulate. At least one contact structure 147 or 149 may be connected to the floating diffusion region 110, and the floating diffusion region 110 may be adjacent to a transmission gate structure TG. The transmission gate structure TG may be adjacent to the photodiode 107 formed inside the pixel separator 103 in a first direction (e.g., Z-axis direction). For example, the first conductivity-type impurity may be an N-type impurity.

When a first bias voltage is input to the transmission gate structure TG, charges generated in the photodiode 107 may not move to the floating diffusion region 110. When a voltage of the transmission gate structure TG increases to a second bias voltage higher than the first bias voltage, charges generated in the photodiode 107 may move to the floating diffusion region 110. For example, the first bias voltage may be a negative voltage, and the second bias voltage may be a positive voltage. An absolute value of the first bias voltage may be smaller than an absolute value of the second bias voltage.

In the example embodiment illustrated in FIG. 3, the floating diffusion region 110 may extend in a second direction (e.g., X-axis direction), a third direction (e.g., Y-axis direction), or the like. However, a shape of the floating diffusion region 110 is not limited to that illustrated in FIG. 3 and may be modified in various manners depending on example embodiments.

The transistors 120 and 130 may provide at least one of a reset transistor RX, a selection transistor SX, and driving transistors DX1 and DX2 included in the pixel circuit. Referring to FIG. 3, a first transistor 120 may include a first gate structure 125 and active regions 123 disposed on both sides of the first gate structure 125, and a second transistor 130 may include a second gate structure 135 and active regions 133 disposed on both sides of the second gate structure 135. An area of each of active regions 123, 127, 133, and 137 may be smaller than an area of the floating diffusion region 110. This may be because the area of the floating diffusion region 110, where charges generated by the photodiode accumulate, needs to be secured to be relatively larger.

On the other hand, the pixels 100 may include the floating diffusion region 110 and at least one impurity region 140 separated from the transistors 120 and 130 in the central area of the one pixel circuit area. The impurity region 140 may not contact the transmission gate structure TG and may be separated from the transmission gate structure TG by a device isolation film 105. In example embodiments, the impurity region 140 may be doped with an impurity of a second conductivity type different from the floating diffusion region 110 and the active regions 123 and 133. The impurity region 140 may be a ground area GND that receives a ground voltage.

Contact structures CS may be disposed in the transmission gate structure TG, the floating diffusion region 110, the active regions 123 and 133, and the impurity region 140.

The contact structures CS may include first type contact structures 157, 159 disposed on the transmission gate structure TG, second type contact structures 147, 149 disposed in the floating diffusion regions 110 and active regions 123 and 133 of the transistors 120 and 130, and third type contact structures 127, 129, 137 and 139 disposed on the gate structures 125 and 135 of the transistors 120 and 130.

The first type (157, 159), the second type (147, 149) and the third type (137, 139, 127, 129) contact structures may respectively include horizontal contact portions 157, 147, 137, and 127 disposed to directly contact and electrically conduction on a contact object of respective elements, and vertical contact portions 159, 149, 139, and 129 disposed on the horizontal contact portions 157, 147, 137, and 127 and electrically connected to an upper interconnection 174.

The vertical contact portions 159, 149, 139, and 129 may be contact vias, and may include a conductive material filling a via hole 161 penetrating through an interlayer insulating layer 160, and may electrically connect the upper interconnection 174 and a lower object. The vertical contact portions 159, 149, 139, and 129 may have a width of an upper surface greater than a width W3 of a lower surface thereof, and may include inclined side surfaces whose width becomes smaller as they go downward. Lower surfaces of the vertical contact portions 159, 149, 139, and 129 may be circular, but are not limited thereto.

The horizontal contact portions 157, 147, 137, and 127 may have an area larger than an area of the lower surface of the vertical contact portions 159, 149, 139, and 129, and for example, may have an area of 1.5 to 10 times the area of the lower surface of the vertical contact portions 159, 149, 139, and 129, and for example, may have an area of 2 to 5 times the area of the lower surface of the vertical contact portions 159, 149, 139, and 129.

Referring to FIGS. 4A and 4B, the pixel circuit area may be defined by the pixel separator 103 formed in a substrate 101, and within one pixel circuit area, two pixel areas PX1 and PX2 or/PX3 and PX4 may be disposed based on the intermediate separation area 102.

The substrate 101 may be a semiconductor substrate. For example, the substrate 101 may be a substrate formed of a semiconductor material, for example, a single crystal silicon substrate.

The photodiode 107 may respectively be formed within the substrate 101 within the two pixel areas PX1 and PX2 or PX3 and PX4, respectively. The photodiode 107 may be adjacent to each transmission gate structure TG in the Z-direction perpendicular to one surface of the substrate 101.

On the other hand, an optical unit 170 may be disposed on a first surface of the substrate 101 adjacent to the photodiode 107 in the Z-direction, which is the vertical direction. The optical unit 170 may include a color filter 171, a grid structure 173, a planarization layer 175, a micro lens 177, and the like. The color filter 171 may be separated from color filters of other adjacent pixels by the grid structure 173 and may transmit light in a predetermined wavelength band. The micro lens 177 may refract light incident on the pixel 100 and focus the light on the photodiode 107. The photodiode 107 may generate charges in response to light passing through the optical unit 170.

On the other hand, pixel areas PX1, PX2, PX3, and PX4 may be disposed on a second surface of the substrate 101, which faces opposite to the first surface that is adjacent to the photodiode 107 in the Z-direction, which is the vertical direction. Accordingly, the optical unit 170 and the pixel areas PX1, PX2, PX3, and PX4 may be disposed on both sides of the photodiode 107 in the first direction, that is, the Z-direction. The pixel areas PX1, PX2, PX3, and PX4 may include the floating diffusion region 110, a transmission gate structure TG adjacent to the floating diffusion region 110, at least one transistor 120, 130, and the like.

On the second surface of the substrate 101, an active region ACT may be defined by the device isolation film 105 within the substrate 101. Source/drain regions 123 and 133 of each circuit element may be doped regions formed within the active region ACT. In example embodiments, some of the areas divided by the device isolation film 105 may be dummy active regions, which are areas in which transistors are not formed. For example, the dummy active region may include a ground area GND.

The circuit elements 120 and 130 may include elements such as transistors including gate electrodes 125 and 135 and source/drain regions 123 and 133. The gate electrodes 125 and 135 may include a semiconductor material, such as silicon, germanium, or a combination thereof. The gate electrodes 125 and 135 may include an n-type or p-type doped layer, but may alternatively include an undoped layer. In example embodiments, the circuit elements 120 and 130 may be driving transistors DX1 and DX2, a reset transistor RX, and a selection transistor SX. However, the types and arrangement relationships of the circuit elements 120 and 130 may vary variously.

The charge generated in the photodiode 107 may accumulate inside the photodiode 107 or move to the floating diffusion region 110 depending on a magnitude of the voltage input to the transmission gate structure TG. For example, while the first bias voltage is input to the transmission gate structure TG, charge is accumulated inside the photodiode 107, and when a second bias voltage greater than the first bias voltage is input to the transmission gate structure TG, charges inside the photodiode 107 may move to the floating diffusion region 110.

The floating diffusion region 110 may include a plurality of regions doped with impurities at different concentrations, but is not limited thereto. When the floating diffusion region 110 includes a plurality of regions, it may be doped at a higher concentration as it moves away from the transmission gate structure TG.

The transmission gate structure TG may include a transmission gate electrode 117, a transmission gate insulating layer 118, a transmission gate spacer 119, and the like. The transmission gate electrode 117 may include a conductive material such as polysilicon, metal, or metal silicide, and the first bias voltage and the second bias voltage described above may be applied to the transmission gate electrode 117. The transmission gate insulating layer 118 may be disposed between the transmission gate electrode 117 and the substrate 101.

The transmission gate electrode 117 may include a first electrode layer and a second electrode layer, and the first electrode layer and the second electrode layer may have different shapes. In an example, the second electrode layer may be disposed between the first electrode layer and the photodiode 107 in the first direction, and a width thereof may become narrower as it approaches the photodiode 107. The second electrode layer may be disposed to be lower than an upper surface of the substrate 101 and buried in the substrate 101, and the first electrode layer may have an area disposed at a higher level than the upper surface of the substrate 101.

The transmission gate insulating layer 118 may be formed along an interface between the transmission gate electrode 117 and the substrate 101. The first electrode layer and the second electrode layer may be offset from each other in the second direction (Y-direction) and disposed in different positions. Therefore, at least a portion of a lower surface of the first electrode layer may not be in direct contact with an upper surface of the second electrode layer, and at least a portion of the transmission gate insulating layer 118 may be disposed between the device isolation film 105 and the first electrode layer in the first direction.

The transmission gate spacer 119 may include silicon nitride or the like, and may be formed only around the first electrode layer. In detail, in a direction parallel to the upper surface of the substrate 101, the second electrode layer may not be adjacent to the transmission gate spacer 119. At least a portion of the transmission gate spacer 119 may be located to be lower than the upper surface of the substrate 101 as illustrated in FIG. 4A, and thus may be disposed inside the substrate 101. At least a portion of the transmission gate spacer 119 may be disposed at the same height as the floating diffusion region 110 in the first direction.

The transmission gate spacer 119 disposed between the floating diffusion region 110 and the first electrode layer may include a first region extending along a side of the transmission gate insulating layer 118 and a second region extending along a side of the floating diffusion region 110. The first region may be formed to be longer than the second region in the first direction. An upper portion of the second region may be separated from the first region in the horizontal direction (e.g., X or Y-direction), and as illustrated in FIG. 4A, the transmission gate spacer 119 may include a valley region between the floating diffusion region 110 and the gate electrode 117.

Gate structures of the transistors 120 and 130 other than the transfer transistor TX may have a shape different from the shape of the transmission gate structure TG. Referring to FIG. 4B, the gate structure of the first transistor 120 may be formed on the substrate 101, and may include a gate electrode 125, a gate insulating layer 128, and a gate spacer (not illustrated). In the Z-direction perpendicular to the upper surface of the substrate 101, the length of each of the gate electrodes 125 may be shorter than the length of the transmission gate electrode 117.

An interconnection area may be disposed on the substrate 101. The interconnection area may include first upper interconnection patterns 174, interconnection vias, and second upper interconnection patterns 181 connected to the transmission gate structure TG, gate electrodes 125 and 135 and the active regions 123 and 133 of circuit elements 120 and 130. The interconnection area may be formed inside the interlayer insulating layer 160 and intermetallic insulating layers 172 and 180 formed on the substrate 101. By the interconnection area, the floating diffusion region 110, the transmission gate structure TG, the transistors 120 and 130 and the like included in the pixel 100 may be electrically connected to each other.

In example embodiments, the pixels 100 may include an insulating liner 161 and a plurality of upper insulating layers 162 and 166.

The insulating liner 161 may be conformally formed on the second surface of the substrate 101. The insulating liner 161 may conformally cover lower gate structures TG, 125, and 135 and the substrate 101, on the gate structures TG, 125, and 135. The insulating liner 161 may include silicon oxide or a low dielectric material. The insulating liner 161 may extend from an insulating liner forming the gate insulating layers 118 and 128 disposed below the gate structures TG, 125, and 135 and may be formed of the same material as a material of the insulating liner forming the gate insulating layers 118 and 128.

A first upper insulating layer 162 may be disposed on the insulating liner 161.

The first upper insulating layer 162 may be disposed to conformally cover upper portions of the gate structures TG, 125 and 135 of respective circuit elements, for example, a transmission gate structure TG, a reset gate electrode, a selection gate electrode, driving gate electrodes 125 and 135, and an insulation liner 161 on the exposed substrate 101. The first upper insulating layer 162 may be a protective film and may include silicon oxide or a low dielectric material to insulate and protect the lower circuit elements from the outside.

A second upper insulating layer 166 may be disposed on the first upper insulating layer 162. The second upper insulating layer 166 may include a different material from the first upper insulating layer 162, and may conformally cover the circuit elements and an upper portion of the first upper insulating layer 162 on the exposed substrate 101, to have a thickness greater than a thickness of the first upper insulating layer 162. The second upper insulating layer 166 may include silicon nitride, silicon nitride, or a low dielectric material. Since the second upper insulating layer 166 includes a different material from the first upper insulating layer 162, the second upper insulating layer 166 may function as an etch stop layer during the process.

The first upper insulating layer 162 and the second upper insulating layer 166 have separate functions and may protect lower circuit elements and the semiconductor substrate 101 by including different materials. A total thickness of the first upper insulating layer 162 and the second upper insulating layer 166 may satisfy 30 to 50 nm, and in detail, may satisfy 30 to 40 nm. Additionally, the second upper insulating layer 166 may have the greatest thickness within the thickness above, and the thickness of the insulating liner 161 may also be included within the total thickness above. For example, the second upper insulating layer 166 may be the thickest, the insulating liner 161 may be the thinnest, and the first upper insulating layer 162 may satisfy the thickness therebetween.

The insulating liner 161 and the first upper insulating layer 162 may be collectively referred to as an oxide layer 165 containing the same material, and may be implemented as silicon oxide layers formed by setting different deposition temperatures during a process. Therefore, crystal sizes of the silicon oxide layers may be different, but the disclosure is not limited thereto.

An interlayer insulating layer 160 may be provided on the substrate 101. The interlayer insulating layer 160 may cover the transmission gate structures TG and the gate electrodes 125 and 135 of the selection transistor SX, the reset transistor RX, and the driving transistors DX1 and DX2, and the exposed substrate 101 therebetween, on the second upper insulating layer 166. The interlayer insulating layer 160 may include a single layer or a multilayer structure of at least one of silicon oxide (SiO), silicon nitride (SIN), silicon nitride (SiON), and a porous low-K dielectric layer.

The intermetallic insulating layers 172 and 180 may be provided on the interlayer insulating layer 160. The intermetallic insulating layers 172 and 180 may include a single-layer or multilayer structure of at least one of silicon oxide (SiO), silicon nitride (SiN), silicon nitride (SiON), and porous insulating films. The first and second upper interconnections 174 and 181 and contact plugs may be disposed between the intermetallic insulating layers 172 and 180. Contact plugs may contain a metal such as tungsten (W), aluminum (Al) or copper (Cu), and in detail, tungsten may be used.

The contact plugs have a pillar shape and may have inclined side surfaces whose width decreases toward the substrate 101.

In example embodiments, the pixels 100 may include a contact structure CS for electrical connection between respective circuit elements. Each contact structure may include horizontal contact portions 157, 147, 137, and 127 and vertical contact portions 159, 149, 139, and 129.

The horizontal contact portions 157, 147, 137, and 127 may be disposed on the transmission gate structure TG, the floating diffusion region 110, and the gate electrodes 125 and 135 of the driving transistors TX1 and TX2, respectively.

Areas of the respective horizontal contact portions 157, 147, 137, and 127 may be different from each other, but are not limited thereto. In detail, the areas of the horizontal contact portions 157, 127, and 137 disposed on the transmission gate structure TG and the gate electrodes 125 and 135 of the driving transistor may be larger than the area of the horizontal contact portion 147 disposed in the floating diffusion region 110, but are not limited thereto.

The horizontal contact portions 157, 147, 137, and 127 may penetrate the first upper insulating layer 162 and the second upper insulating layer 166, and lower surfaces of the horizontal contact portions 157, 147, 137, and 127 may directly contact lower circuit structures, for example, upper surfaces of the gate electrodes 117, 125, and 135 and an upper surface of the floating diffusion region 110. Accordingly, the horizontal contact portions 157, 147, 137, and 127 may also be disposed to penetrate the insulating liner 161 below the first upper insulating layer 162.

Accordingly, the insulating liner 161 and the first and second upper insulating layers 162 and 166 are removed, thereby forming first openings 167 exposing the upper surfaces of the lower gate electrodes 117, 125, and 135 and the upper surface of the floating diffusion region 110, and the horizontal contact portions 157, 147, 137, and 127 may be formed by filling the first openings 167.

The horizontal contact portions 157, 147, 137, and 127 may have a plurality of interlayer structures and may include at least a double-layer structure.

The horizontal contact portions 157, 147, 137, and 127 may further include an extended area S2 that fills the first opening 167 and extends to the upper surface of the adjacent second upper insulating layer 166. Accordingly, the horizontal contact portions 157, 147, 137, and 127 may include a contact area S1 filling the first opening 167 penetrating from the insulating liner 161 to the second upper insulating layer 166, and the extended area S2 extending from the contact area S1 and extending to the upper surface of the second upper insulating layer 166.

Therefore, the area and a shape of the horizontal contact portions 157, 147, 137, and 127 may be designed in various manners depending on a size of the extended area S2, and accordingly, a process freedom of the upper contact plug-in vertical contact portions 159, 149, 139, and 129 may be secured.

Referring to FIGS. 5A and 5B, each of the horizontal contact portions 157, 147, 137, and 127 may have two conductive layers 151 and 152.

The horizontal contact portions 157, 147, 137, and 127 are disposed in the lower portion, and may include, as a lower conductive layer, a first conductive layer 151 formed along the side and bottom surfaces of the first opening 167 and filling the first opening 167. Hereinafter, descriptions of the first conductive layer 151 may be understood as descriptions of the lower conductive layer. The first conductive layer 151 may include hafnium (Hf) or titanium (Ti), but is not limited thereto. The first conductive layer 151 includes a first portion of the contact area S1 filling the first opening 167 and a second portion of the extended area S2 extending over the second upper insulating layer 166, and a thickness h2 of the first portion may be different from the thickness of the second portion. An area of the first portion (e.g., an area of the contact area S1) may be larger than an area of the second portion (e.g., an area of the extended area S2), and the area of the first portion may be smaller than an area of the upper surfaces of the gate electrodes 117, 125, and 135. Since the first portion of the first conductive layer 151 is formed by filling the first opening 167, the thickness of the first conductive layer 151 may be generally defined as the thickness h2 of the first portion. Additionally, the thickness h2 of the first conductive layer 151 may be greater than the depth h1 of the first opening 167. Accordingly, the first conductive layer 151 may be formed to protrude above the first opening 167, but is not limited thereto.

A second conductive layer 152 may be further formed as a pad conductive layer on the first conductive layer 151. Hereinafter, descriptions of the second conductive layer 152 may be understood as descriptions of the pad conductive layer.

The second conductive layer 152 may be formed conformally along the first conductive layer 151, and may be formed on the first conductive layer 151, and may thus have the same thickness in the contact area S1 and in the extended area S2.

The second conductive layer 152 may partially include, in its surface, a concave area in which a level of an uppermost surface decreases toward a center of the first opening 167, but is not limited thereto.

The second conductive layer 152 may be a conductive barrier and may block conductive material from diffusing into the first conductive layer 151 in a lower portion when forming a contact plug that may be placed in an upper portion. The second conductive layer 152 may be a metal nitride such as titanium nitride (TiN) or tantalum nitride (TaN), but is not limited thereto.

As an example, in a case in which the upper contact plug-in vertical contact portions 159, 149, 139, and 129 include tungsten (W), and when depositing tungsten, the metal forming the lower first conductive layer 151, for example, titanium, and tungsten gas (WF6) may react to oxidize the lower first conductive layer 151 of titanium. Since the first conductive layer 151 substantially performs electrical contact between the lower circuit element and the upper vertical contact portions 159, 149, 139, and 129, a damage to the first conductive layer 151 may lead to a damage to the silicon material, resulting in leakage current in the floating diffusion region 110.

Therefore, by further forming a second conductive layer 152 on the first conductive layer 151, device reliability may be secured by using the second conductive layer 152 that acts as a barrier to chemical reaction between the upper vertical contact portions 159, 149, 139, and 129 and the first conductive layer 151.

The thickness h2 of the first conductive layer 151 in the contact area S1 may be greater than a thickness of the second conductive layer 152, and the thickness of the first conductive layer 151 in the extended area S2 may be equal to or smaller than the thickness of the second conductive layer 152.

Accordingly, on the second upper insulating layer 166, the thickness of the second conductive layer 152 may be equal to or greater than the thickness of the first conductive layer 151. In this manner, by forming the second conductive layer 152 sufficiently thick, electrical connection is possible without damaging the first conductive layer 151, and accordingly, a damage to the silicon material of the lower gate structures TG, 125 and 135 or the substrate 101 may be prevented.

In detail, as illustrated in FIG. 5A, the contact structure CS on the transmission gate structure TG may include the horizontal contact portion 157 and the vertical contact portion 159. As previously described, the horizontal contact portion 157 may include the first conductive layer 151 formed to extend by filling the first opening 167 that exposes the upper surface of the gate electrode 117 of the transmission gate structure TG, and the second conductive layer 152 on the first conductive layer 151. The horizontal contact portion 157 may have a rectangular shape that is longer in one direction (e.g., X-direction) as illustrated in FIG. 3, but alternatively, may have a square shape, or may have any other shape such as a circular or elliptical shape. A contact plug may be disposed on the horizontal contact portion 157, as the vertical contact portion 159, and may form a via structure for electrical connection while physically contacting the horizontal contact portion 157. The contact plug forming the vertical contact portion 159 may be formed in a pillar shape extending vertically from an upper surface of the interlayer insulating layer 160 to an upper surface of the second conductive layer 152 of the horizontal contact portion 157, and may contain a conductive metal material such as tungsten (W), aluminum (Al), copper (Cu), or the like.

The vertical contact portion 159 may be formed only of a filling metal material that fills the via hole 161, rather than a multilayer structure, and may not include separate conductive barriers on the side and bottom surfaces of the vertical contact portion 159. Therefore, even if the area of a lower surface of the vertical contact portion 159 becomes very small, it is possible to prevent the area from being further reduced due to deposition of a conductive barrier, and the vertical contact portion 159 may secure a sufficient contact area, and maintain low resistance during contact by directly bonding without a conductive barrier.

The lower surface of the vertical contact portion 159 may have a smaller area than an area of an upper surface of the vertical contact portion 159, and the area of the lower surface of the vertical contact portion 159 may be 1/10 to ⅔ of an area of the horizontal contact portion 157, but is not limited thereto.

The width W3 of the lower surface of the vertical contact portion 159 may be smaller than a width of a lower portion of the horizontal contact portion 157, for example, a width W1 of the first opening 167. The vertical contact portion 159 may be disposed to be deviated from a center of the horizontal contact portion 157 toward one side. For example, when the horizontal contact portion 157 has a rectangular shape that is longer in the X-direction, the vertical contact portion 159 may be disposed on one side, in detail, to be close to the intermediate separation area 102, but the disclosure is not limited thereto.

The lower surface of the vertical contact portion 159 may be disposed to be lower than the upper surface of the second conductive layer 152 of the horizontal contact portion 157. For example, a level of the lower surface of the vertical contact portion 159 may be lower than a level of the uppermost surface of the second conductive layer 152, but may be disposed at a higher level than an upper surface of the first conductive layer 151.

For example, even when the vertical contact portion 159 is formed to be recessed into a portion of the second conductive layer 152, the vertical contact portion 159 may be disposed to secure a first separation distance I1 from the upper surface of the first conductive layer 151. Accordingly, the first conductive layer 151 and the vertical contact portion 159 may be spaced apart by the second conductive layer 152, thereby sufficiently preventing chemical reaction therebetween.

A height h4 of the vertical contact portion 159 may satisfy 2 to 20 times a height h3 of the horizontal contact portion 157, and in detail, may be 5 to 15 times the height h3 of the horizontal contact portion 157. Respective vertical contact portions 159 may have different heights depending on the height of the lower circuit element, and the areas and widths of the lower surfaces of the respective vertical contact portions 159 may be different from each other accordingly.

In detail, as illustrated in FIG. 5B, the height d4 of the contact plug forming the vertical contact portion 149 of the floating diffusion region 110 may be greater than a height of the contact plug forming the vertical contact portion 159 of the transmission gate structure TG.

Referring to FIGS. 3, 4A, 4B and 5B, the horizontal contact portion 147 disposed in the floating diffusion region 110 may include the first conductive layer 151 that extends by filling the first opening 167 that opens the substrate 101 in which the floating diffusion region 110 is disposed, and the second conductive layer 152 on the first conductive layer 151. The horizontal contact portion 147 may have a smaller area than an area of the first conductive layer 151 on the gate structure TG, as illustrated in FIG. 3, and may have a square shape, or alternatively, may have a rectangular shape, or may have any other shape such as a circular or elliptical shape. A contact plug may be disposed on the horizontal contact portion 147, as the vertical contact portion 149, and may form a via structure for electrical connection while physically contacting the horizontal contact portion 147. The contact plug forming the vertical contact portion 149 may be formed in a pillar shape extending vertically from the upper surface of the interlayer insulating layer 160 to the upper surface of the second conductive layer 152 of the horizontal contact portion 157, and may include tungsten (W), aluminum (Al), or copper (Cu).

A lower surface of the vertical contact portion 149 may have a smaller area than an area of an upper surface thereof, and an area of the lower surface of the vertical contact portion 149 may satisfy 1/10 to ⅔ of the area of the horizontal contact portion 157, and in detail, may be ⅓ to ½ of the area of the horizontal contact portion 157, but is not limited thereto.

The width W3 of the lower surface of the vertical contact portion 149 may be smaller than a width of the lower portion of the horizontal contact portion 157, for example, the width W1 of the first opening 167. The vertical contact portion 149 may be disposed at a center of the horizontal contact portion 147, but is not limited thereto.

The lower surface of the vertical contact portion 149 may be disposed below the upper surface of the second conductive layer 152 of the horizontal contact portion 147. For example, a level of the lower surface of the vertical contact portion 149 may be lower than the level of the uppermost surface of the second conductive layer 152, but may be disposed at a higher level than the upper surface of the first conductive layer 151.

For example, even when the vertical contact portion 159 is formed by recessing a portion of the second conductive layer 152, the vertical contact portion 159 may be disposed to secure the first separation distance I1 from the upper surface of the first conductive layer 151. Therefore, chemical reaction between the first conductive layer 151 and the vertical contact portion 159 may be sufficiently prevented.

Referring to FIGS. 3 and 4B, like the transmission gate structure TG, the horizontal contact portions 127 and 137 (hereinafter collectively referred to as 127) disposed on the gate electrodes 125 and 135 of the transistors 120 and 130 other than the transmission gate structure TG may include the first conductive layer 151 that extends by filling the first opening 167 that opens the upper surface of the gate electrodes 125, and the second conductive layer 152 on the first conductive layer 151. The horizontal contact portion 127 may have an area equal to or smaller than an area of the first conductive layer 151 on the transmission gate structure TG, as illustrated in FIG. 3, and may have a larger area than an area of the first conductive layer 151 on the floating diffusion region 110. The second conductive layer 152 may have a rectangular shape that is longer in the first direction (e.g., X-direction), but alternatively, may have a square shape, or may have a shape of a circle or an oval. A contact plug may be disposed as a vertical contact portion 129 on the horizontal contact portion 127. The layer structure and connection of the vertical contact portion 129 and the horizontal contact portion 127 may be the same as the layer structure and connection of the vertical contact portion 159 and the horizontal contact portion 157 on the transmission gate structure TG.

A width of a lower surface of the vertical contact portion 129 may be smaller than the width of the lower portion of the horizontal contact portion 157, for example, the width of the first opening 167. The vertical contact portion 159 may be disposed at the center of the horizontal contact portion 157, but is not limited thereto.

The first and second upper interconnections 174 and 181 may be disposed in multiple layers on the interlayer insulating layer 160 and between the intermetallic insulating layers 172 and 180, and may connect the gate electrodes 117, 125 and 135 and the source/drain regions 123 and 133 of respective transistors and the floating diffusion region 110 depending on a pixel circuit design, thereby applying an electrical signal.

As illustrated in FIG. 4B, the gate electrodes 125 and 135 of the source follower transistor, which is the driving transistor DX, and the floating diffusion region 110 may be electrically connected to each other. To this end, the vertical contact portions 149 and 129 may be connected through the first upper interconnection 174 on the interlayer insulating layer 160.

In FIGS. 3 and 4B, the first upper interconnection 174 connecting the gate electrodes 125 and 135 of the source follower transistor, which is the driving transistor DX, and the floating diffusion region 110, is illustrated as being disposed across the pixel separator 103, but is not limited thereto, and may be implemented in various manners in a multilayer structure on the intermetallic insulating layers 170 and 180.

In the above, the contact structures including the horizontal contact portions 157, 147, 137, and 127 and the vertical contact portions 159, 149, 139, and 129, on the transmission gate structure TG, the floating diffusion region 110, and the driving gate electrodes 125 and 135, are described, but in example embodiments of the disclosure, a contact structure including the horizontal contact portions 157, 147, 137, and 127 and the vertical contact portions 159, 149, 139, and 129 may be applied to contacts of respective circuit elements.

In detail, the contacts of gate electrodes of transistors other than the transmission gate structure TG may be implemented in the same manner as the contact structures of the driving gate electrodes 125 and 135 of FIG. 4B, and the contact of the source/drain regions 123 and 133 of respective transistors and the contact of the ground area 140 may be implemented in the same manner as the contact structure of the floating diffusion region 110.

In this manner, in the area in which the contact plugs forming the vertical contact portions 159, 149, 139, and 129 are disposed, while implementing a contact structure including horizontal contact portions 157, 147, 137, and 127 as landing pads for electrical contact in a larger area with lower circuit elements, a contact structure including the horizontal contact portions 157, 147, 137, and 127 and the vertical contact portions 159, 149, 139, and 129 may be formed in a multilayer structure.

The upper surface exposed externally in the multilayer structure of the horizontal contact portions 157, 147, 137, and 127 may be formed of a conductive barrier, and thus, the vertical contact portions 159, 149, 139, and 129 may be implemented using only a filling conductive metal material without a separate conductive barrier, and therefore, the vertical contact portions 159, 149, 139, and 129 may secure the contact area and may be formed without damaging the lower first conductive layer 151.

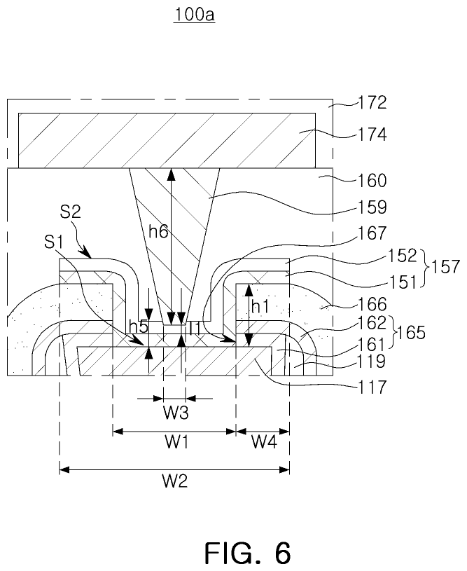

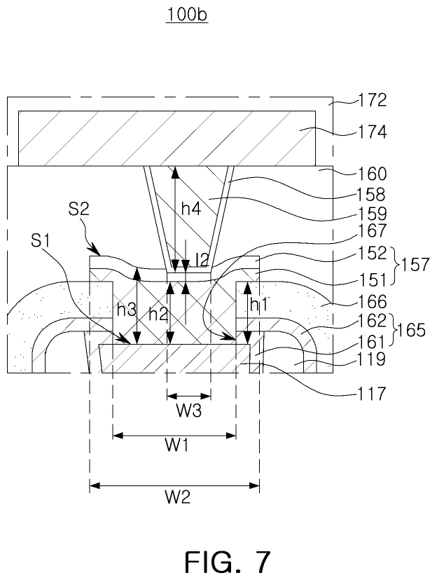

Below, with reference to FIGS. 6 and 7, modifications of the contact structure including the vertical contact portions 159, 149, 139, and 129 and the horizontal contact portions 157, 147, 137, and 127, respectively, according to one or more example embodiments will be described.

FIGS. 6 and 7 illustrate the horizontal contact portion 157 and the vertical contact portion 159 on the transmission gate structure TG, but are not limited thereto, and may be equally applied to the horizontal contact portions 147 and 127 and the vertical contact portions 149 and 129 disposed on the floating diffusion region 110 and the gate electrodes 125 and 135 of other transistors.

Referring to FIG. 6, a pixel 100a may be identical to the pixel 100 of FIGS. 4 to 5B except for shapes of the horizontal contact portion 157 and the vertical contact portion 159, which are contact structures.

The horizontal contact portion 157 may include a first conductive layer 151 uniformly formed to a first thickness along the side and bottom surfaces of the first opening 167 exposing the gate electrode 117. The second conductive layer 152 may be uniformly formed on the first conductive layer 151 to a second thickness. The second thickness may be greater than the first thickness, but is not limited thereto.

Both the first conductive layer 151 and the second conductive layer 152 may be formed conformally along the first opening 167, and the depth h1 of the first opening 167 may be greater than a total thicknesses h5 of the horizontal contact portion 157. Accordingly, the horizontal contact portion 157 may be formed concavely along the first opening 167 and have a flat upper surface on the bottom surface of the first opening 167. The vertical contact portion 159 may be disposed on the flat upper surface to enable physical and electrical connection between the two structures.

The area of the contact area S1 including the flat upper surface may be formed to be equal to or smaller than the area of the extended area S2. For example, the extended area S2 extends widely and outwardly of the first opening 167, over the second upper insulating layer 166, and may thus has a width W2 that is larger than a width of the contact area S1. The width W2 of the extended area S2 includes a width corresponding to a difference between W2 and W1, for example, 2×W4.

The upper contact plug-in vertical contact portion 159 may be formed in a pillar shape extending vertically from the upper surface of the interlayer insulating layer 160 to the upper surface of the second conductive layer 152 of the horizontal contact portion 157, and may have a greater length h6 with respect to the horizontal contact portion 157 in FIG. 4A.

The lower surface of the vertical contact portion 159 may have a smaller area than the area of the upper surface of the vertical contact portion 159, and the area of the lower surface of the vertical contact portion 159 may satisfy ½ to ⅓ of the contact area S1 of the horizontal contact portion 157, but is not limited thereto.

The width W3 of the lower surface of the vertical contact portion 159 may be smaller than the width of the lower portion of the horizontal contact portion 157, for example, the width W1 of the first opening 167. The vertical contact portion 159 may be disposed biased to one side of the horizontal contact portion 157, but may alternatively be disposed in the center of the horizontal contact portion 157.

The lower surface of the vertical contact portion 159 may be disposed to be lower than the level of the uppermost surface of the second conductive layer 152 within the first opening 167 of the horizontal contact portion 157. For example, the level of the lower surface of the vertical contact portion 159 may be lower than the level of the upper surface of the second conductive layer 152, but may be disposed at a higher level than the upper surface of the first conductive layer 151.

For example, even when the vertical contact portion 159 is formed by partially recessing the second conductive layer 152, the vertical contact portion 159 may be disposed to secure the separation distance I1 from the upper surface of the first conductive layer 151. Therefore, the chemical reaction between the first conductive layer 151 and the vertical contact portion 159 may be sufficiently blocked.

Referring to FIG. 7, a pixel 100b may be identical to the pixel 100 of FIGS. 4 to 5B except for the shapes of the horizontal contact portion 157 and the vertical contact portion 159.

The shape and stacked structure of the horizontal contact portion 157 may be the same as those in FIG. 5A, and for example, may include the first conductive layer 151 filling the first opening 167 exposing the gate electrode 117 and the second conductive layer 152 on the first conductive layer 151.

However, the horizontal contact portion 157 may also include the first conductive layer 151 and the second conductive layer 152, which are conformally formed along the side and bottom surfaces of the first opening 167.

The vertical contact portion 159 of FIG. 7 may further include a conductive barrier 158 that covers side and bottom surfaces of the via hole 161 formed in the interlayer insulating layer 160.

The conductive barrier 158 may function as a diffusion prevention layer to prevent the filling conductive metal material from diffusing into the interlayer insulating layer 160, and may be formed of a conductive material, but is not limited thereto.

The conductive barrier 158 may include metal nitride, and for example, may include titanium nitride (TiN), tantalum nitride (TaN), or the like. The conductive barrier 158 may include the same material as a material of the second conductive layer 152, but is not limited thereto. For example, if the second conductive layer 152 includes titanium nitride, the conductive barrier 158 may include tantalum nitride.

When the conductive barrier 158 is formed, the second conductive layer 152 may have a thickness smaller than the thickness of the second conductive layer 152 in FIGS. 5A and 6.

Therefore, when the conductive barrier 158 is formed, even if a separation distance I2 is relatively further reduced than the first separation distance I1, a barrier of the conductive barrier 158 may prevent the filling gas (WF6) from reacting with the lower first conductive layer 151 when filling tungsten, which is a filling metal material.

Accordingly, the via hole 161 may be formed without considering the remaining separation distance 12 of the second conductive layer 152, thereby further securing proofing of a process error.

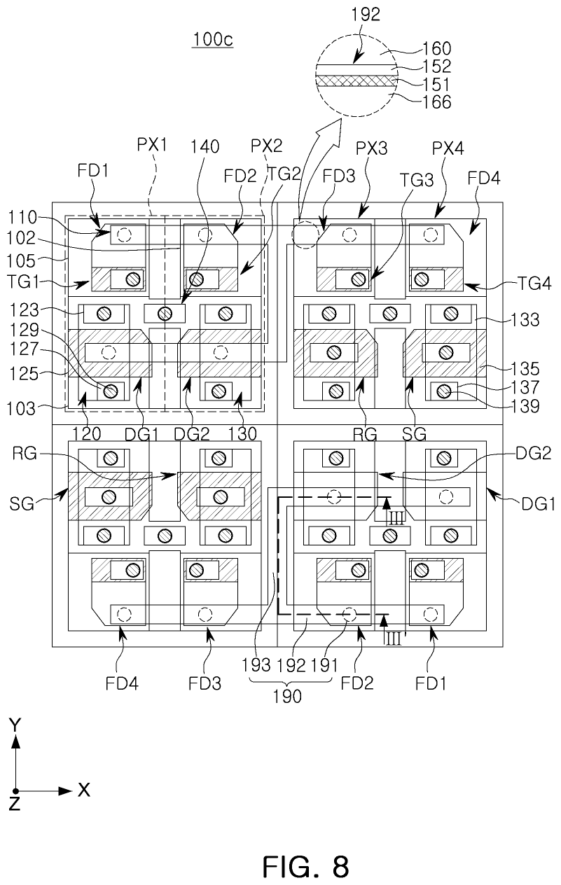

Hereinafter, a pixel according to one or more example embodiments will be described with reference to FIGS. 8 to 10B.

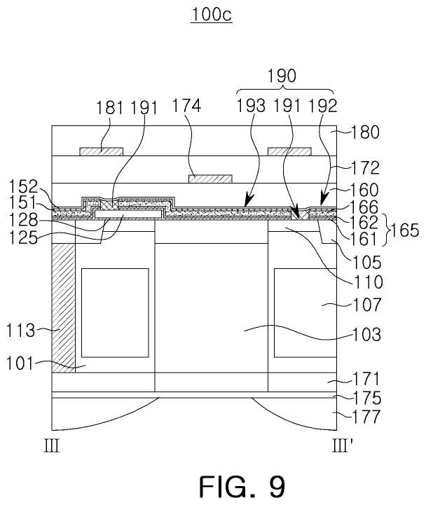

FIG. 8 is a diagram schematically illustrating pixels of an image sensor according to one or more example embodiments, and FIG. 9 is a cross-sectional view illustrating a cross section taken along line III-III′ of the pixels of FIG. 8.

Pixels 100c of an image sensor 1 in FIGS. 8 and 9 may be the same as those in FIGS. 3 to 7 except that they further include a connection pattern 190.

The pixels 100c of the image sensor 1 in FIGS. 8 and 9 may further include the connection pattern 190 with respect to the pixels 100a described above.

The connection pattern 190 may connect the gate electrodes 125 and 135 of the driving transistors DX1 and DX2 to the plurality of floating diffusion regions FD1-FD4 and 110. In detail, the connection pattern 190 may fill the first opening 167 that opens from the insulating liner 161 to the second upper insulating layer 166, on an object to be electrically connected. A first conductive layer 151 may be formed as a lower pattern conductive layer, and a second conductive layer 152 may be formed as a pattern conductive layer (or an upper pattern conductive layer) on the first conductive layer 151, thereby providing a structure of a horizontal contact portion 157.

The connection pattern 190 may be understood as a structure in which the extended area S2 extends long from the horizontal contact portion 157, and depending on an area through which the connection pattern 190 passes, the area may be defined as a first connection area 191 within the first opening 167, a second connection area 192 passing within the pixel areas PX1-PX4, and other third connection area 193. The first connection area 191 and the second connection area 192 may overlap with each other and be connected in the vertical Z-direction, and the second connection area 192 and the third connection area 193 may be connected in the horizontal direction on an X-Y plane.

The connection pattern 190 may include the first connection areas 191, the second connection area 192 connecting the first connection areas 191 to each other on the plurality of floating diffusion regions FD1-FD4, 110, and the third connection region 193 extending from the second connection region 192 and provided on the device isolation film 105, as illustrated in FIG. 8. The third connection area 193 may extend to a position in which the gate electrodes 125 and 135 of the driving transistors DX1 and DX2 are disposed, and may be connected to the second connection area 192 on the gate electrodes 125 and 135 of the driving transistors DX1 and DX2, and the second connection area 192 may be connected to the lower first connection area 191, thereby forming one connection pattern 190. The connection pattern 190 may be understood as including a plurality of contact portions covering the first openings that open from the insulating liner 161 to the second upper insulating layer 166 and contacting the driving gate electrode 125, 135 and the floating diffusion region 110; and an extension portion connecting the plurality of contact portions along an upper surface of the upper insulating layer 166. The extension portion may simultaneously connect the contact portions of a plurality of floating diffusion regions of two or more pixels adjacent to each other.

The connection pattern 190 may be disposed in various manners depending on the circuit design, and as the connection pattern 190 is disposed on the second upper insulating layer 166, electrical connection of spaced elements is possible by extending the horizontal contact portion 157, without forming the vertical contact portion 159 on the horizontal contact portion 157.

In this manner, a number of vertical contact portions 159, which are through-vias penetrating the interlayer insulating layer 160, may be dramatically reduced, thereby increasing the degree of freedom in layout, and the interconnections 174 and 181 on the upper intermetallic insulating layers 172 and 180 may be simplified.

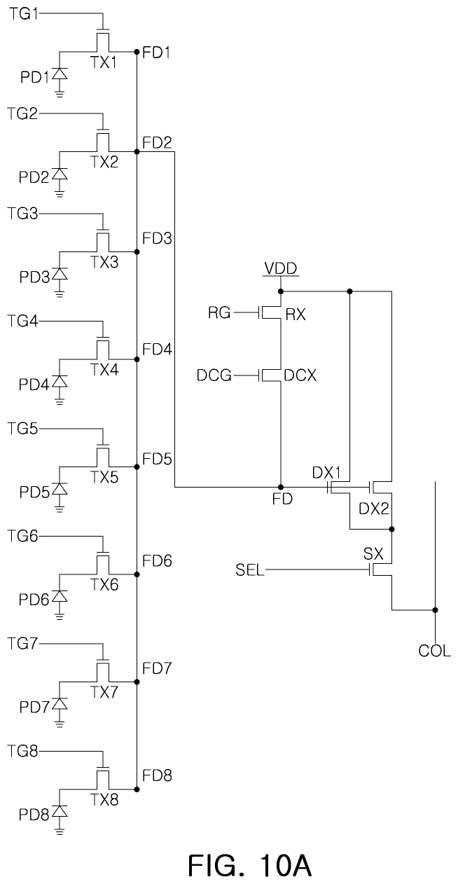

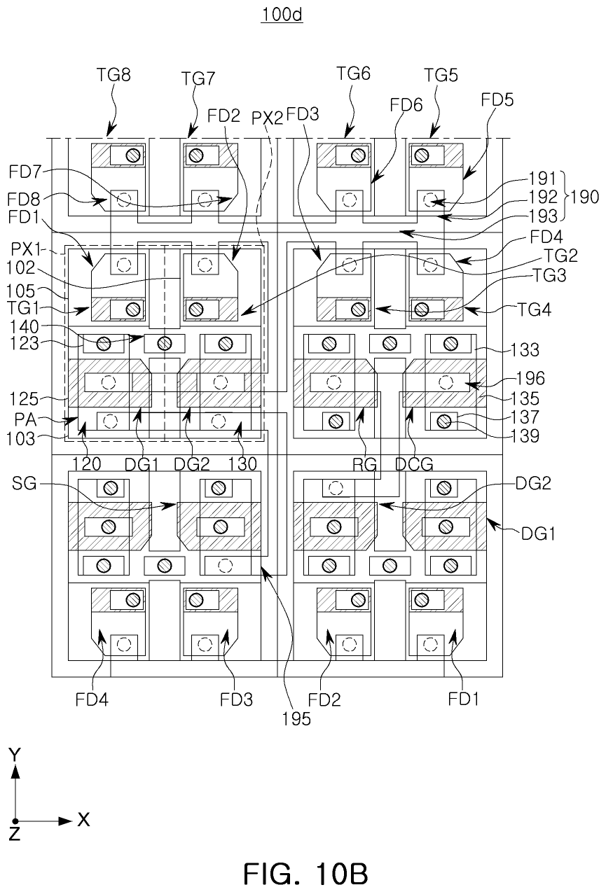

FIG. 10A is a circuit diagram schematically illustrating the pixel circuit of an image sensor according to one or more example embodiments, and FIG. 10B is a diagram schematically illustrating the pixel circuit of FIG. 10A.

The pixel circuit of the image sensor 1 in FIG. 10A may be a circuit diagram schematically illustrating a pixel circuit including 8 photodiodes PD1-PD8, 8 transmission gate structures TG1-TG8, 8 floating diffusion regions FD1-FD8, and 5 transistors RX, DCX, DX1, DX2 and SX.

Referring to FIG. 10A, the first photodiode PD1 and the first transfer transistor TX1 of the first pixel PX1 may be connected to the first floating diffusion node FD1. Likewise, the second to eighth photodiodes PD2-PD8 of the second to eighth pixels PX2-PX8 may be connected to the second to eighth floating diffusion nodes FD2-FD8 through second to eighth transfer transistors TX2-TX8, respectively. The integrated floating diffusion node FD may be implemented by connecting the floating diffusion nodes FD1-FD8 included in the first to eighth pixels PX1-PX8, respectively, to each other using an interconnection pattern or the like. The first to eighth transfer transistors TX1-TX8 may be implemented by transmission gate structures TG1-TG8, respectively.

The pixel circuit may include a reset transistor RX, a dual conversion gain transistor DCX, first and second driving transistors DX1 and DX2, and a selection transistor SX. The reset transistor RX and the dual conversion gain transistor DCX are connected in series with each other, and the integrated floating diffusion node FD may be defined therebetween. The reset transistor RX and the dual conversion gain transistor DCX may be controlled by a reset control signal RG and a dual conversion gain signal DG, respectively.

For example, among eight transistors included in fourth pixel circuit areas, two transistors may be connected in parallel to provide first and second driving transistors DX1 and DX2, and two transistors may be connected in series with each other to provide a reset transistor RX and a dual conversion gain transistor DCX. On the other hand, among the eight transistors, one transistor may function as a selection transistor SX, and the remaining three transistors may be dummy transistors, but are not limited thereto. By connecting and disconnecting respective floating diffusion nodes FD1-FD8 and the integrated floating diffusion node FD, the conversion gain of the image sensor may be changed.

The circuit arrangement of FIG. 10B may be an example arrangement of the pixel circuit of FIG. 10A.

Referring to FIG. 10B, in pixels 100d of the image sensor 1, four pixel circuit areas disposed in a 2×2 shape in the horizontal direction (X-axis direction) and vertical direction (Y-axis direction), and two pixel areas are disposed in each of the four pixel circuit areas. Thus, it would be understood that the first to eighth pixels PX1-PX8 may be allocated to eight pixel areas in a 4×2 form, respectively.

The structure of each pixel circuit area is as described above, and for example, each of the first to eighth pixel areas may have the structure as previously described in FIGS. 3 to 7. Accordingly, each of the first to eighth pixels PX1 to PX8 may include a floating diffusion region 110, a transmission gate structure TG, and a transistor 120, 130, and the like.

In an example embodiment illustrated in FIG. 10B, the first to fourth pixels PX1-PX4 and the fifth to eighth pixels PX5-PX8 may be disposed in the same shape. The first to fourth pixels PX1 to PX4 may be disposed such that the floating diffusion regions FD1 to FD4 included in the first to fourth pixels PX1 to PX4 are adjacent to each other. Additionally, the fifth to eighth pixels PX5 to PX8 may be disposed such that the floating diffusion regions FD5 to FD8 included in the fifth to eighth pixels PX5 to PX8 are adjacent to each other. In addition, the floating diffusion regions FD5-FD8 included in the fifth to eighth pixels PX5-PX8 may be disposed symmetrically with the floating diffusion regions FD1-FD4 included in the first to fourth pixels PX1-PX4, with respect to an axis of the pixel separator 103, to face each other.

By crowding the eight floating diffusion regions FD1-FD8 as described above, the connection pattern 190 may be disposed efficiently.

The pixels 100d of FIG. 10B may be substantially the same as the pixels 100c of FIGS. 3 and 8 and may differ only in the configuration of the connection patterns 190, 195, and 196.

Each of the first to eighth pixels PX1-PX8 may include only one transistor 120, 130, and eight transistors may be disposed in four pixel circuit areas forming one pixel group. In example embodiments, eight transistors included in one pixel group may be implemented with first and second driving transistors DX1 and DX2 connected in parallel, serially-connected reset transistor RX and dual conversion gain transistor DCX, a selection transistor SX, and three dummy transistors, regarding the eight floating diffusion regions FD1-FD8 included in the first to fourth pixels PX1-PX4. The dummy transistors may be applied as additional driving transistors and reset transistors, and may be designed in various manners depending on the circuit design.

The connection patterns 190, 195, and 196 may fill a first opening 167, which opens from the insulating liner 161 to the second upper insulating layer 166, on an object to be electrically connected, and a first conductive layer 151 may be formed, which may be the same as the structure of the horizontal contact portion 157 of FIGS. 3 to 5B in which the second conductive layer 152 is formed on the first conductive layer 151, and the connection pattern 190 of FIGS. 8 and 9.

The connection patterns 190, 195, and 196 may be understood as a structure in which the extended area extends and elongated from the horizontal contact portion 157, and the areas thereof may be defined as a first connection area 191 within the first opening 167, a second connection area 192 passing through the pixel circuit area, and a third connection area 193, depending on the area through which the connection patterns 190, 195, and 196 pass. The first connection area 191 and the second connection area 192 may overlap with each other and be connected in the vertical Z-direction, and the second connection area 192 and the third connection area 193 may be connected in the horizontal direction on the X-Y plane.

The connection patterns 190, 195, and 196 may include the first connection pattern 190 connecting eight floating diffusion regions FD1-FD8 and two driving gate electrodes 125 and 135.

Additionally, the second connection pattern 195 may connect the drains 123 and 133 of the two driving transistors DX1 and DX2 and the source 133 of the selection transistor SX. Additionally, the third connection pattern 196 may connect the source/drain regions 123 and 133 for serial connection of the reset transistor RX and the dual conversion gain transistor DCX. This third connection pattern 196 may extend to a portion of the dummy transistor, but is not limited thereto.

In this manner, electrical connection between a plurality of circuit elements connected to each other through the interconnections 174 and 181 in the intermetallic insulating layers 172 and 180 on the interlayer insulating layer 160 may be obtained by applying the connection patterns 190, 195 and 196 in which the horizontal contact portion 157 is extended. Therefore, the need for formation of via holes 161 and filling of vias in the interlayer insulating layer 160 may be significantly reduced, and unnecessary capacitance may be reduced, thereby improving signal transmission efficiency.

In this manner, the number of vertical contact portions 159, which are through-vias penetrating through the interlayer insulating layer 160, may be significantly reduced, thereby increasing the freedom of layout and simplifying interconnection on the upper intermetallic insulating layer.

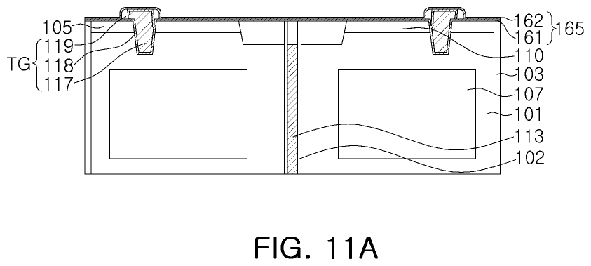

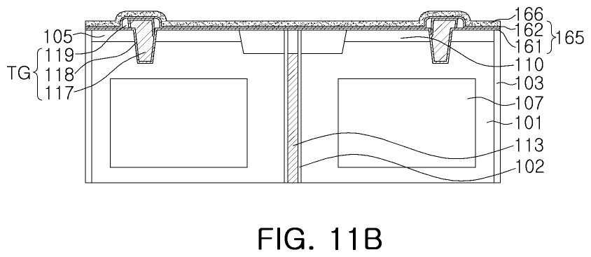

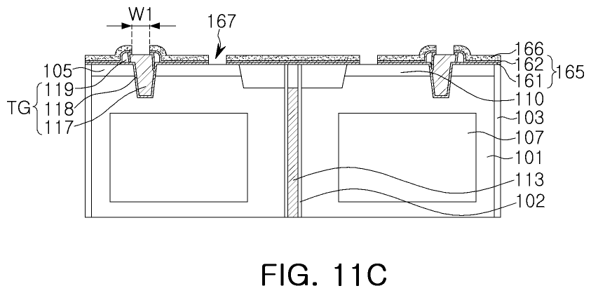

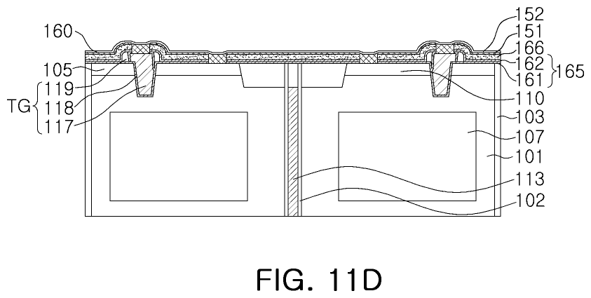

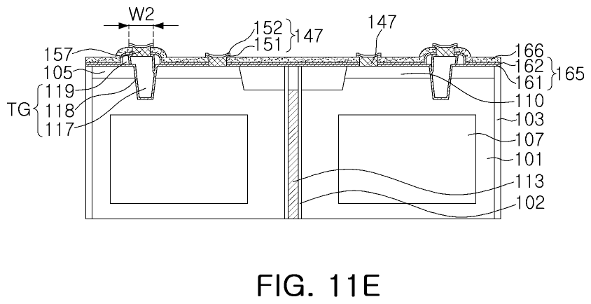

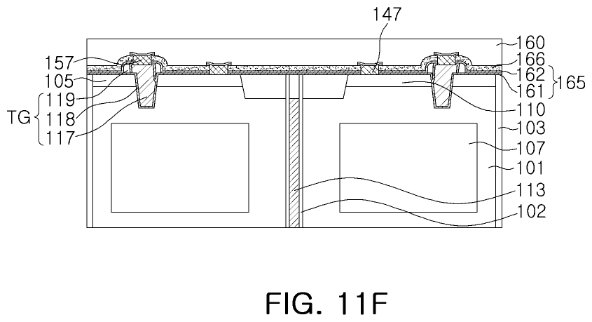

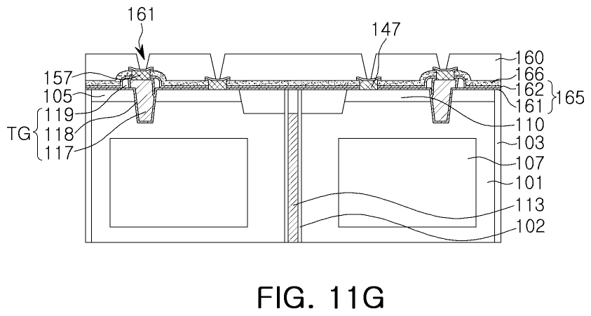

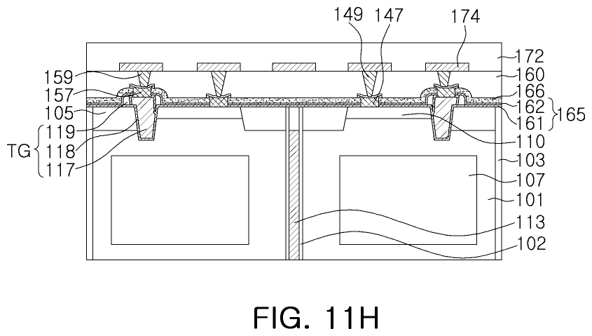

FIGS. 11A to 11H are cross-sectional views schematically illustrating a method of manufacturing an image sensor according to one or more example embodiments. FIGS. 11A to 11H illustrate areas corresponding to FIG. 4A.

Referring to FIG. 11A, a method of manufacturing an image sensor according to one or more example embodiments may include preparing a substrate 101, forming a photodiode 107 within the substrate 101, and then forming a device isolation film 103 on the surface to define an active region ACT, and forming circuit elements 120 and 130 and a first upper insulating layer 162 covering the same, on the substrate 101.

The photodiode 107 may be formed with photoelectric conversion elements PD in the substrate 101, and the device isolation film 103 may be formed to define the active region of the substrate 101, and by forming an insulating liner 161 on the substrate 101, depositing a semiconductor material layer, and performing a patterning process, circuit elements 120 and 130 may be formed. The transmission gate structure TG and other transistor gate electrodes 125 and 135 may have different patterns depending on shapes thereof. The transmission gate structure TG may extend below the surface of the substrate 101 to have a longer depth to reach the area adjacent to the photodiode 107 inside the substrate 101. At this time, the heights of the transistor gate electrodes 117, 125, and 135 to the upper surface of the substrate 101 may be the same. An insulating liner 161 may be formed to cover the respective gate electrodes 117, 125, and 135 and the exposed upper surface of the substrate 101, and the first upper insulating layer 162 may be continuously formed.

The insulating liner 161 and the first upper insulating layer 162 may be formed by depositing the same material, and the deposition temperatures may be set to be different from each other. The insulating liner 161 may be deposited at a low temperature, and the first upper insulating layer 162 may be deposited at a higher temperature than the insulating liner 161 to form silicon oxide or a low dielectric layer. The first upper insulating layer 162 may be deposited to have a greater thickness than the thickness of the insulating liner 161.

Referring to FIG. 11B, the second upper insulating layer 166 may be formed on the first upper insulating layer 162.

The second upper insulating layer 166 may conformally cover the entire first upper insulating layer 162 and may be formed by depositing a material different from the first upper insulating layer 162. For example, the second upper insulating layer 166 may be formed using an atomic layer deposition (ALD) method or a chemical vapor deposition (CVD) method. The thickness of the second upper insulating layer 166 may be greater than the thickness of the first upper insulating layer 162, and for example, may have 3 to 4 times the thickness, but is not limited thereto. The second upper insulating layer 166 may be formed of a material different from the first upper insulating layer 162 and having etch selectivity, such as silicon nitride (SiN) or silicon nitride (SiON).

Referring to FIG. 11C, a first opening 167 may be formed to open an area for respective contacts of the circuit elements.

The first opening 167 may be an opening exposing the upper surface of the gate electrode 117 of the transmission gate structure TG, the upper surfaces of the gate electrodes 125 and 135 of the other transistors 120 and 130, or the upper surface of the floating diffusion region 110, or may be an opening exposing the source/drain regions 123 and 133 or the ground areas 140 of respective transistor elements, which are areas for other contacts.

This first opening 167 may be formed by removal from the second upper insulating layer 166 to the insulating liner 161 to expose the upper surface of the circuit element and may be formed in various shapes, such as a circle, oval, rectangle, or square, with one side having a first width W1. The first opening 167 may be formed by a photo mask and etching process, but is not limited thereto.

Referring to FIG. 11D, a first conductive layer 151 may be formed to cover the first opening 167, and a second conductive layer 152 may be formed continuously covering the first conductive layer 151.

The first conductive layer 151 and the second conductive layer 152 may be formed by a chemical vapor deposition process of a conductive material layer, and the first conductive layer 151 may be deposited to fill the first opening 167 and protrude from the upper surface of the first opening 167 to cover the entire pixel area. The first conductive layer 151 may be formed to have a first thickness h2 over the first opening 167, and a highly conductive metal such as titanium (Ti) or hafnium (Hf) may be used as the first conductive layer 151, but is not limited thereto.

Next, the second conductive layer 152 may be conformally deposited on the first conductive layer 151, and the second conductive layer 152 may be formed to have a second thickness that is equal to or greater than the protruding thickness of the first conductive layer 151 on the second upper insulating layer 166. At this time, depending on the area of the first opening 167, when the first conductive layer 151 is deposited, an upper surface including a concave area toward the center of the first opening 167 may be provided, and the second conductive layer 152 may be formed conformally along the upper surface including the concave area. However, when the area of the first opening 167 is relatively large, a flat area may be formed in the central area excluding the edge area of the first opening 167.

Next, referring to FIG. 11E, the first and second conductive layers 151 and 152 may be etched to form the horizontal contact portion 157 of the contact structure.

In the case of the horizontal contact portion 157, a mask layer is formed on the first conductive layer 151 and the second conductive layer 152 over each first opening 167, to have a second width W2 greater than the first width W1, and is then etched to form the horizontal contact portion 157. In this manner, even if dry etching and wet etching are sequentially performed on patterning of the horizontal contact portion 157, the second upper insulating layer 166 may function as an etch stop layer to prevent damage to the lower first upper insulating layer 162.

Accordingly, the first opening 167 of FIGS. 4A and 4B may be filled and the horizontal contact portion 157 may be formed to have an extended area S2 around the first opening 167.

At this time, the first conductive layer 151 may remain in the extended area S2, and the size and area of the horizontal contact portion 157 may be varied depending on the length of the extended area S2. If the extended area S2 is formed long and extends to the extended area S2 of another horizontal contact portion, the connection pattern 190 of FIG. 8 or 10 may be formed.

As illustrated in FIG. 11F, an interlayer insulating layer 160 may be formed on the substrate 101. For example, the interlayer insulating layer 160 may be formed by chemical vapor deposition. The interlayer insulating layer 160 may be formed thick enough to evenly cover the substrate 101 and the gate structures TG, 125, and 135, on the second upper insulating layer 166 and the horizontal contact portion 157. The interlayer insulating layer 160 may be formed of a single layer of at least one of silicon oxide (SiO), silicon nitride (SiN), silicon nitride (SiON), and a porous low-K dielectric layer, or a multilayer thereof, but the disclosure is not limited thereto.

Referring to FIG. 11G, a via hole 161 exposing the horizontal contact portion 157 may be formed in the interlayer insulating layer 160.

After the interlayer insulating layer 160 is formed flat, a mask may be deposited on the interlayer insulating layer 160 and etched to respectively form the via holes 161 exposing the upper surface of the horizontal contact portion 157. The mask may be removed after forming the via hole 161.

When forming the via hole 161, a portion of the surface of the second conductive layer 152 may be depressed, but may be depressed only to a predetermined depth of the second conductive layer 152, to ensure a first separation distance I1 or more, such that a portion of the second conductive layer 152 remains on the first conductive layer 151. The width of the open upper portion of each via hole 161 is larger than the width of the lower portion, and the width W3 of the open lower surface may be smaller than the first width W1, which is the width of the first opening 167 of the horizontal conductive layer 157.

Referring to FIG. 11h, the vertical contact portion 159 may be formed by filling the via hole 161 with a conductive metal material.

In detail, a conductive metal material is deposited to form the upper portion while filling the via hole 161, and this deposition may proceed to cover the interlayer insulating layer 160.

Afterwards, the vertical contact portion 159 may be formed by etching using chemical and physical polishing to expose the interlayer insulating layer 160. In the case in which tungsten (W) is applied as a conductive metal material for the vertical contact portion 159, when the WF6 gas applied as the deposition gas reacts with the first conductive layer 151 of the horizontal contact portion 157, for example, titanium (Ti), titanium in the first conductive layer 151 may actively react with WF6 gas and be oxidized. This chemical reaction may lead to corrosion of the first conductive layer 151 and damage to the silicon of the substrate 101 or the lower gate electrodes 117, 125 and 135. In the case of the transmission gate structure TG, leakage current may flow into the floating diffusion region 110. In the disclosure, the second conductive layer 152 may be applied as a conductive barrier on the first conductive layer 151, and the second conductive layer 152 is formed to a sufficient thickness on the first conductive layer 151 to prevent contact between the first conductive layer 151 and the vertical contact portion 159 with the deposition gas. Therefore, tungsten deposition in the vertical contact portion 159 may be performed without damaging the lower first conductive layer 151.

In addition, when depositing tungsten in the vertical contact portion 159, a separate conductive barrier is deposited on the side and bottom surfaces of the via hole 161 and then tungsten may be directly deposited rather than filling with tungsten, such that the narrow area of the bottom surface of the via hole 161 may be sufficiently filled with tungsten, thereby significantly reducing contact resistance.

After forming the first upper interconnection 174 on the vertical contact portion 159, the interconnection process of forming the intermetallic insulating layer 172 and forming the second upper interconnection 181 thereon may be repeated in various manners according to the circuit design, and then, the optical unit 170 may be formed on one surface of the substrate 101, thereby forming the pixels 100 of FIGS. 4A and 4B.

As set forth above, according to one or more example embodiments, damage to lower devices during via contact may be significantly reduced by forming expansion patterns for electrical connection of devices in a pixel circuit. In addition, by forming the pad, which is the expansion pattern, as a multilayer structure, it may be implemented only with filling conductive metal material without a conductive barrier layer of the via, thereby ensuring contact stability and significantly reducing contact resistance even when the via size is miniaturized. In addition, damage to the lower device may be prevented by disposing expansion patterns not only on the transmission gate structure but also on contacts of the floating diffusion region and contacts of the driving gate structure.

In addition, the interconnection structure on the interlayer insulating layer may be simplified by performing electrical connection between various elements through a connection pattern extending from the expansion pattern, rather than through interconnection on the interlayer insulating layer.

While example embodiments have been illustrated and described above, it will be apparent to those skilled in the art that modifications and variations could be made without departing from the scope of the disclosure as defined by the appended claims.

What is claimed is:

1. An image sensor comprising:
a substrate including a first surface and a second surface opposing the first surface;
a first photoelectric conversion region for a first pixel in the substrate;
a floating diffusion region in the substrate;
a transfer gate configured to move charges generated in the first photoelectric conversion region to the floating diffusion region;
a first conductive layer configured to electrically connect to the transfer gate and vertically overlapping with the transfer gate in a first direction perpendicular to the first surface of the substrate; and
a first vertical contact including a first surface and a second surface, wherein the first surface of the first vertical contact is configured to connect to the first conductive layer,
wherein the first vertical contact is vertically overlapping with the first conductive layer in the first direction,
wherein the first surface of the first vertical contact has a first width in a second direction perpendicular to the first direction,
wherein the first conductive layer has a second width in the second direction and the second width is at least 1.5 times greater than the first width,
wherein the first conductive layer is spaced apart from the first surface of the substrate, and
wherein the transfer gate is in contact with the first surface of the substrate.

2. The image sensor of claim 1, wherein the second surface of the first vertical contact has a third width in the second direction, and
wherein the second width is greater than the third width.

3. The image sensor of claim 2, wherein a portion of the transfer gate extends into the first surface of the substrate.

4. The image sensor of claim 3, further comprising:
a second photoelectric conversion region for a second pixel in the substrate;
a third photoelectric conversion region for a third pixel in the substrate; and
a fourth photoelectric conversion region for a fourth pixel in the substrate,
wherein the floating diffusion region is shared by the first to fourth photoelectric conversion regions.

5. The image sensor of claim 4, wherein the first vertical contact includes a first material and the first conductive layer has a second material different from the first material.

6. The image sensor of claim 4, wherein a portion of the first vertical contact extends into the first conductive layer.

7. The image sensor of claim 5, wherein the first conductive layer includes a metal material.

8. The image sensor of claim 4, wherein the first pixel further comprising:
a second vertical contact including a first surface; and
a second conductive layer including a first surface connected to the first surface of the second vertical contact,
wherein the first surface of the second vertical contact has a fourth width in the second direction and the first surface of the second conductive layer has a fifth width in the second direction,
wherein the fifth width is at least 1.5 times greater than the fourth width, and
wherein the floating diffusion region, the second conductive layer, and the second vertical contact are vertically overlapping with each other in the first direction.

9. The image sensor of claim 8, wherein a distance from the first surface of the substrate to the first conductive layer is closer than a distance from the first surface of the substrate to the second conductive layer.

10. The image sensor of claim 9, wherein the second width is different from the fifth width.

11. The image sensor of claim 9, wherein the first vertical contact has a first height in the first direction and the second vertical contact has a second height in the first direction different from the first height.

12. The image sensor of claim 9, wherein the first conductive layer has a third height in the first direction and the second conductive layer has a fourth height in the first direction, and
wherein the third height is the same has the fourth height.

13. The image sensor of claim 9, further comprising:
a dual conversion gain transistor; and
a reset transistor,
wherein the first to fourth pixels are configured to connect to the reset transistor and the dual conversion gain transistor.

14. An image sensor comprising:
a substrate including a first surface and a second surface opposing the first surface;
a first photoelectric conversion region for a first pixel in the substrate;
a second photoelectric conversion region for a second pixel in the substrate;
a device isolation film between the first pixel and the second pixel;
a floating diffusion region in the substrate;
a transfer gate configured to move charges generated in the first photoelectric conversion region to the floating diffusion region;
a first conductive layer configured to electrically connect to the transfer gate; and
a first vertical contact including a first surface, the first surface in contact with the first conductive layer,
wherein the transfer gate, the first conductive layer, and the first vertical contact are vertically overlapping with each other in a first direction perpendicular to the first surface of the substrate,
wherein the first surface of the first vertical contact has a first width in a second direction perpendicular to the first direction,
wherein the first conductive layer has a second width in the second direction and the second width is greater than the first width,
wherein the first conductive layer is spaced apart from the first surface of the substrate,
wherein the transfer gate is in contact with the first surface of the substrate, and
wherein the first conductive layer is offset from the device isolation film in the second direction.

15. The image sensor of claim 14, further comprising:
a second vertical contact including a first surface; and
a second conductive layer including a first surface connected to the first surface of the second vertical contact,
wherein the first surface of the second vertical contact has a fourth width in the second direction and the first surface of the second conductive layer has a fifth width in the second direction,
wherein the fifth width is greater than the fourth width, and
wherein the second conductive layer is offset from the device isolation film in the second direction.

16. The image sensor of claim 15, wherein the second conductive layer is in contact with the first surface of the substrate.

17. The image sensor of claim 15, wherein the second conductive layer is vertically overlapping with the floating diffusion region in the first direction.

18. The image sensor of claim 17, wherein the first conductive layer a first height in the first direction and the second conductive layer has a second height in the first direction, and
wherein the first height is the same has the second height.

19. The image sensor of claim 17, wherein the first conductive layer includes a metal material.

20. The image sensor of claim 17, further comprising:
a third photoelectric conversion region for a third pixel in the substrate; and
a fourth photoelectric conversion region for a fourth pixel in the substrate,
wherein the floating diffusion region is shared by the first to fourth photoelectric conversion regions.
